(19) United States
(12) Patent Application Publication
(10) Pub. No.: US 2010/0159395 A1
(43) Pub. Date: Jun. 24, 2010

(54) METHOD OF DIFFERENTIATION OF UNEXPOSED AND EXPOSED PLANOGRAPHIC PRINTING PLATES

(76) Inventors: John R. Fyson, London (GB); John M. Higgins, Cambridge (GB)

Correspondence Address: Raymond L. Owens;Patent Legal Staff, Eastman Kodak Company, 343 State Street, Rochester, NY, 14650-2201, US

(21) Appl. No.: 12/630,882

(22) Filed: Dec. 4, 2009

(30) Foreign Application Priority Data
Dec. 18, 2008 (GB) 0823033.6

(51) Int. Cl. G03F 7/20

(52) U.S. Cl. 430/302

(57) ABSTRACT

The invention relates to a method of differentiating an unexposed planographic printing plate from an exposed planographic printing plate by means of making a planographic printing plate comprising a substrate having thereon one or more layers of aluminum oxide, and one or more layers of radiation-sensitive titanium dioxide coated thereon and excluding an organic hydrophobic material or a binder within or above a radiation-sensitive layer, the method comprising depositing at least the one or more layers of titanium dioxide by vapour deposition and exposing the one or more layers to radiation without that exposure causing an ablative effect.

### FIELD OF THE INVENTION

The invention relates to a method of differentiating an unexposed planographic printing plate from an exposed planographic printing plate, and in particular a lithographic printing plate, by vapour deposition of a radiation-sensitive compound on a substrate therefore. The radiation-sensitive compound is titanium dioxide which is applied, preferably by atomic layer deposition, onto aluminum oxide on a substrate.

### BACKGROUND OF THE INVENTION

Offset lithography is the one of the most widely used forms of printing and is characterized by having the image and non-image areas in the same plane (planographic). The image and non-image areas have different wetting characteristics such that, on press, the hydrophilic (water-loving) non-image areas of the printing plate are wetted by water or a dampening solution and only the hydrophobic or oleophilic (oil-loving) image areas are wetted by ink, which is subsequently transferred or ‘offset’ onto the surface of a material upon which the image is to be reproduced, such as paper, cloth or plastics, commonly by the use of an intermediate ‘blanket’ roller.

Many long-run, commercial, planographic printing plates comprise a grained and anodized aluminum layer on which is coated an ink-receptive, hydrophobic layer. Initiating the production of image and non-image areas is usually achieved by selectively exposing the plate to some form of radiation, for example ultra-violet, visible or infra-red radiation. The plate is then processed to remove unwanted, non-image areas of the ink-receptive layer and reveal the appropriate non-image areas of the hydrophilic layer beneath. This can be done in a number of ways, for example, by using a chemical process, by dissolution, by washing, sometimes with some abrasion, or by ablation, all using specific stand-alone devices or performed ‘on-press’. It is often necessary to apply a layer of gum to the non-image areas to improve the plate performance. Waterless planographic printing plates use an overlying silicone layer to form the non-image areas, since silicone has a very low surface energy and is not wetted by the special lithographic ink used for waterless printing. In common with the more conventional printing plates, a processing step removes the unwanted material, in this case the selected areas of the silicone layer, to reveal appropriate ink-receptive image areas beneath.

The wetting characteristics of solid surfaces are governed by the chemical properties and the microstructure of the surfaces. It is well-known that both hydrophilic and hydrophobic surface properties can be enhanced by certain levels of surface roughness (see for example, “Physical Chemistry of Surfaces”, A. W. Adamson, 5^{th} edition, Wiley & Sons, New York, 1990) and many plates, such as, for example, those comprising gained and anodized aluminum, rely on such an effect to produce hydrophilic surfaces suitable as non-image areas on lithographic printing plates.

The production of the image and non-image regions prior to printing by the exposure of a plate selectively to some form of radiation can in some cases be based on the use of metal oxides, sulfides or nitrides coated as thin layers onto a suitable substrate. In particular, it is known that some metal oxides, when exposed to ultra-violet light with sufficient energy to promote an electron into the conduction band, become substantially more hydrophilic and hence are ‘radiation-sensitive’. In addition, the same exposure process can also result in the destruction of organic materials that are in contact with the metal oxide surface (see for example, “Photocatalytic Purification of Water and Air”, D. F. Ollis and H. Al-Ekabi, Proceedings of the First International Conference on TiO₂ Photocatalytic Purification and Treatment of Water and Air, London, Ontario, Canada, 1993, Elsevier, Amsterdam). If the organic material is hydrophobic, the resulting difference in wetting characteristics between exposed and unexposed areas may be sufficient to allow lithographic printing to take place.

Examples of the use of such photocatalytic mechanisms for printing plates are described by Suda et al. in a number of patents and applications, including US Patent Publication No. 2005/0092198 and U.S. Pat. Nos. 6,732,654; 6,978,715; 6,637,336; 6,564,713 and 7,205,094. In such cases the photocatalyst layer contains titanium dioxide, preferably with significant anatase form, and the organic hydrophobic material is coated as a separate, overlying layer. These patents disclose different means of applying the particulate photocatalyst and the hydrophobic layer, including the use of Chemical Vapour Deposition, which is a process wherein the photocatalyst is formed in a vapour phase above the substrate and then adheres to the substrate, often as multiple layers. US Patent Publication No. 2005/0092198 discloses that this process should be carried out from 400° C. to 800° C.

Kobayashi et al. describe in US Patent Publication No. 2008/0085478 that a similar titanium dioxide layer structure can be used for a number of applications, including printing. Kobayashi et al. also describe in U.S. Pat. No. 7,252,923 a ‘two-part’ process, whereby the titanium dioxide photocatalyst layer and organic hydrophobic material are separate elements which are brought into contact temporarily such that, upon selective exposure to ultra-violet radiation, the photocatalyst layer changes the wetting character of the other element. After exposure the two sheets are separated, leaving a printing plate comprising hydrophilic and hydrophobic regions and a photocatalyst element that can be reused.

Kasai et al in U.S. Pat. No. 6,232,034 discuss the use of anatase titanium oxide particles in a matrix of a hydrophobic material that changes wetting characteristics on exposure to light. Similarly, Akio et al. in JP 11305422 describe photocatalyst particles which become hydrophilic on exposure to light. Ooishi et al. in U.S. Pat. No. 6,833,225 disclose making a printing plate by sputtering titanium dioxide onto pre-grained aluminum and then treating this surface with a hydrophobic material.

Riepenhoff et al. in U.S. Pat. No. 6,976,426 describe a process of making a reusable printing form comprising a particulate photocatalyst layer combined with a binder that changes wetting characteristics when exposed to either ultra-violet light or heating. Ikeda et al, in JP 10250027 disclose a printing system that uses a titanium dioxide plate which can be erased by heat, allowing for its reuse. The titanium dioxide used is particulate and forms the major part of the coating, the remaining materials in the coating being unspecified. Mori et al. in U.S. Pat. No. 7,032,514, describe a planographic printing press comprising a printing plate with a photocatalyst layer formed on a heat insulating layer and a means of applying a hydrophobic layer, whereby the wetting characteristics are changed when exposed to either ultra-violet light or an additional heat treatment in the range 40° C. to 200° C.

A different approach from utilizing vapour deposited metal inorganic layers to make printing plates is disclosed by Ellis et al. in U.S. Pat. No. 6,045,964. In this method the printing member comprising a metal oxide layer is exposed in an imagewise fashion using an infrared laser so as to ablate selected areas away to form a printing plate. This patent also discloses the inclusion of a colorant in the underlying substrate or polymeric layer to render the image visible after exposure.

### Problem to be Solved by the Invention

It is useful for the image on a printing plate to be visible to the unaided eye after exposure, such that there is an optical density differential between the unexposed and exposed image areas, in order that the image can be checked and that the plate will not be re-exposed in error. Radiation-sensitive colorants such as dyes can be added but this complicates the process and adds to the cost.

### SUMMARY OF THE INVENTION

In accordance with the present invention there is provided a method of differentiating an unexposed planographic printing plate from an exposed planographic printing plate by means of making a planographic printing plate comprising a substrate having thereon one or more layers of aluminum oxide, and one or more layers of radiation-sensitive titanium dioxide coated thereon and excluding an organic hydrophobic material or a binder within or above a radiation-sensitive layer, the method comprising depositing at least the one or more layers of titanium dioxide by vapour deposition and exposing the one or more layers to radiation without that exposure causing an ablative effect.

### Advantageous Effect of the Invention

By coating one or more layers of titanium oxide onto one or more layers of aluminum oxide on a substrate by vapour deposition, and preferably by ALD, and exposing the plate to radiation, it has been found that there is an optical density differentiation between the image areas of the unexposed and the exposed plate, which is measurable by a densitometer but is also clearly visible to the unaided eye. As a result, the image can be readily checked and the plate will not be re-exposed in error.

The substrate material can be any planar material that has a surface coating of aluminum oxide that needs no treatment except, in some circumstances, cleaning before coating. An aluminum sheet can be grained and anodized to give a surface layer of white aluminum oxide. Alternatively a thin layer of aluminum oxide can be coated by the vapour deposition method described below onto any substrate that will tolerate the coating temperature. No processing or chemicals are required to prepare the printing plates, which can be put on a planographic printing plate and used immediately.

The coating method using vapour deposition, and in particular Atomic Layer Deposition, hereinafter ALD, is fast and of low cost, since only a thin layer of material has to be applied. The apparatus can be scaled to coat any width of substrate and can coat ‘roll-to-roll’. The deposition process can be carried out at low temperatures and at atmospheric pressure. The layer deposited is tough and strongly adheres to any substrate and no binder or additional hydrophobic organic material is required as in the most usual large-scale, wide-area layer manufacturing processes, although a layer of, for example, plastic may be superimposed, if required, on a metal substrate. The manufacture of the titanium dioxide is carried out simultaneously to the deposition process. Although the afore-mentioned patent literature teaches in the case of titanium dioxide the necessity for it to be in the anatase form, this has been found to be unnecessary for the present invention, since titanium dioxide made at below 200° C., although not anatase, is still efficacious.

### BRIEF DESCRIPTION OF THE DRAWINGS

The invention will now be described with reference to the accompanying drawings in which:

FIG. 1 is a flow chart describing the steps of an atomic layer deposition process used in the present invention;

FIG. 2 is a cross-sectional side view of an embodiment of a distribution manifold for atomic layer deposition that can be used in the present process;

FIG. 3 is a cross-sectional side view of an embodiment of the distribution of gaseous materials to a substrate that is subject to thin film deposition;

FIGS. 4A and 4B are cross-sectional views of an embodiment of the distribution of gaseous materials schematically showing the accompanying deposition operation;

FIG. 5 shows the X-ray diffraction angles of titanium dioxide made at a number of different temperatures. Also included are the expected positions of the different forms of naturally occurring forms of titanium dioxide: anatase (101), rutile (110) and brookite (211). These are compared to those of titanium dioxide, formed by ALD at a number of different temperatures in accordance with the present invention. At 100° C. and 150° C. there is no anatase present in the coating and new forms of titanium dioxide are present that are neither rutile nor brookite.

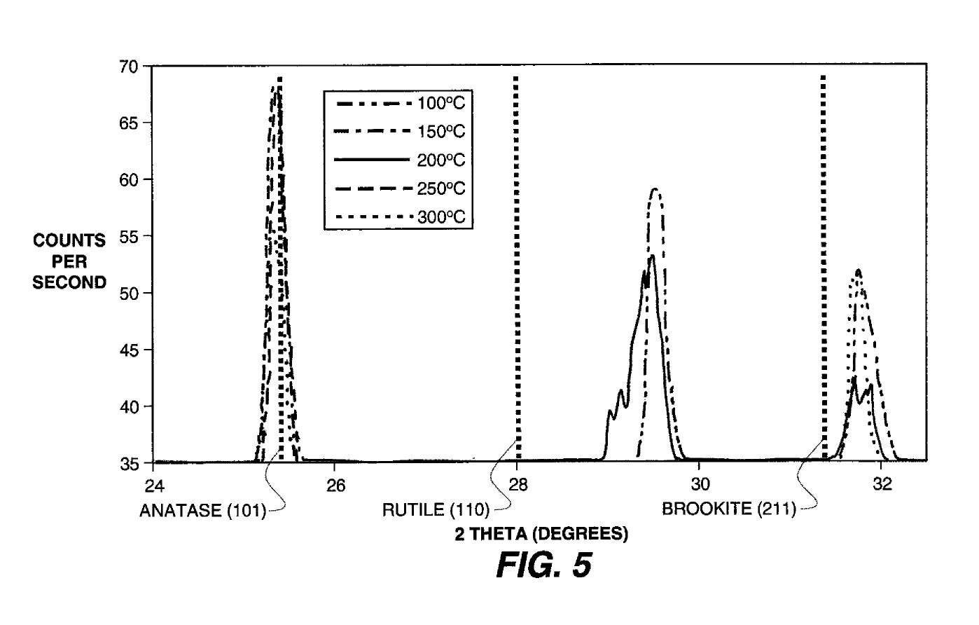

### DETAILED DESCRIPTION OF THE INVENTION

The printing plate substrate is coated with aluminum oxide by any suitable method. This can include graining and anodizing the surface of an aluminum sheet as is well known in the art. Alternatively the aluminum oxide can be coated by the same method as described to coat the titanium dioxide, using however trimethylaluminium instead of titanium tetrachloride.

The method of application of the titanium dioxide to a substrate comprising aluminum to form a planographic printing plate in accordance with this invention is by vapour deposition and preferably by using ALD such as described, for example by D. H. Levy, D. Freeman, S. F. Nelson, P. J. Cowdery-Corvan, L. M. Irving, Applied Physics Letters, 92, 192101 (2008) and in US Patent Publication Nos. 2007/0238311 and 2006/0194157), which can be used at atmospheric pressure and can be scaled to any size. The method is carried out at relatively low temperatures, generally from about 20° C. to 300° C., preferably from about 100° C. to 250° C. In addition, the reactions take place on the substrate surface and only one atomic layer of material is applied at a time, such that the titanium dioxide layer is generally less than 100 nm and preferably less then 25 nm in thickness. The material is essentially planar and continuous and not particulate. In particular no binder or additional hydrophobic material is required to adhere the titanium dioxide to the printing plate.

ALD, sometimes known as atomic layer epitaxy, ALE, and specifically spatial atomic layer deposition, (spALD), is a self-limiting, sequential surface chemistry method that deposits conformal thin films of materials onto substrates of varying compositions. ALD is similar in chemistry to Chemical Vapour Deposition, except that the ALD reaction breaks the Chemical Vapour Deposition reaction into two or more partial reactions, keeping the precursor materials separate during the reaction sequence, as described by S. M. George in J. Phys. Chem. 1996, 100, 13121-13131, Smith, Donald (1995) “Thin-Film Deposition: Principles and Practice” MacGraw-Hill). ALD can be used to deposit several types of thin films, including various metal oxides, sulfides and nitrides especially those of titanium and in particular titanium dioxide, as used in accordance with the present invention.

The printing plate can be made by applying to a substrate one or more layers of titanium dioxide. Titanium dioxide has a high band gap energy, is chemically stable, non-toxic and is readily available. The hydrophilicity of the titanium dioxide layer increases on exposure to radiation of sufficient energy to exceed the energy band-gap of the metal compound. The resulting difference in wetting characteristics is sufficient to allow formation of image and non-image areas such that, on a planographic printing press, hydrophilic non-image areas of the printing plate are wetted by water, or a dampening solution, and only the hydrophobic/oleophilic, ink-receptive, image areas are wetted by ink.

The substrate can be any planar material coated with aluminum oxide, preferably with the potential to be formed such that it is flexible, with a surface that can be roughened or textured. Examples are sheet metals such as aluminum, copper, stainless steel, alloys, and polymers such as polythene terephthalate (PET), polyethylene naphthalate (PEN) and polyamide, many types of paper, flexible glass and composites thereof.

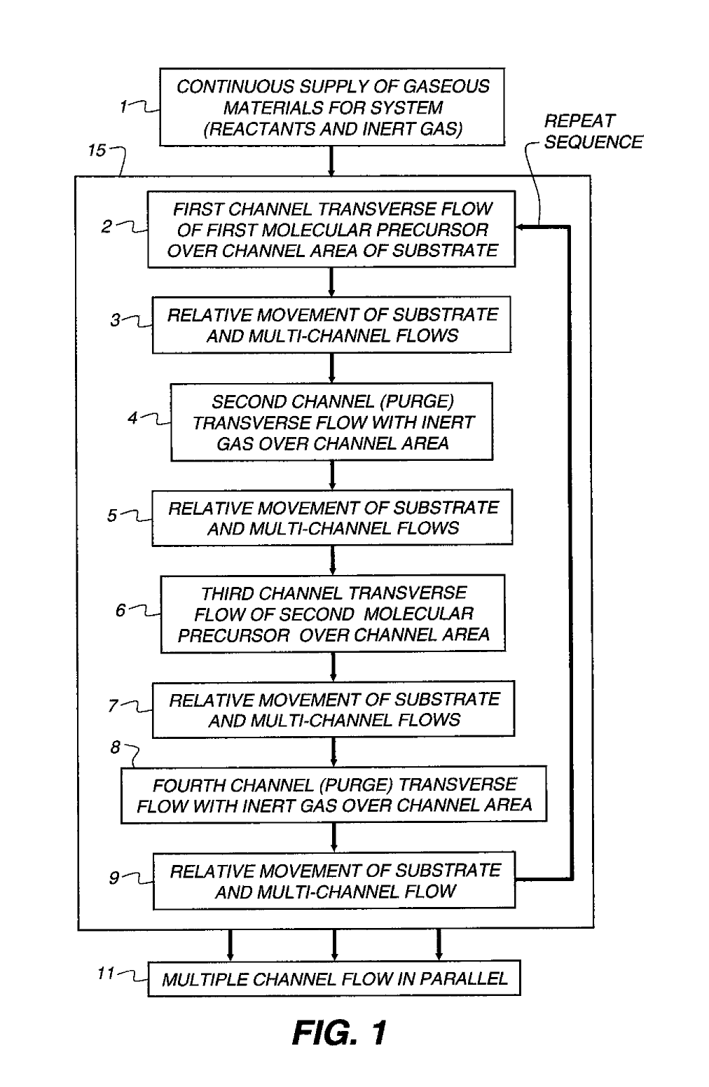

FIG. 1 is a generalized step diagram of a process for practising the present invention. Two reactive gases are used: a first molecular precursor and a second molecular precursor. Gases are supplied from a gas source and can be delivered to the substrate, for example, via a distribution manifold. Metering and valving apparatus for providing gaseous materials to the distribution manifold can be used.

As shown in Step 1, a continuous supply of gaseous materials for the system is provided for depositing a thin film of material on a substrate. The steps in Sequence 15 are sequentially applied. In Step 2, with respect to a given area of the substrate (referred to as the channel area), a first molecular precursor or reactive gaseous material is directed to flow in a first channel transversely over the channel area of the substrate (and substantially parallel to the surface of the substrate) and reacts therewith. In Step 3 relative movement of the substrate and the multi-channel flows in the system occurs, which sets the stage for Step 4, in which second channel (purge) flow with inert gas occurs over the given channel area. Then, in Step 5, relative movement of the substrate and the multi-channel flows sets the stage for Step 6, in which the given channel area is subjected to ALD in which a second molecular precursor also now transversely flows over the given channel area of the substrate and reacts with the previous layer on the substrate to produce (theoretically) a monolayer of a desired material. The first molecular precursor is a titanium-containing compound in gaseous form (for example, a titanium compound such as titanium tetrachloride) and the material deposited is titanium dioxide. In such a process, the second molecular precursor can be, for example, a non-metallic oxidizing compound or a hydrolyzing compound, such as water.

In Step 7, relative movement of the substrate and the multi-channel flows then sets the stage for Step 8 in which again an inert gas is used, this time to sweep excess second molecular precursor from the given channel area from the previous Step 6. In Step 9, relative movement of the substrate and the multi-channels occurs again, which sets the stage for a repeat sequence, back to Step 2. The cycle is repeated as many times as is necessary to establish a desired film or layer. The steps may be repeated with respect to a given channel area of the substrate, corresponding to the area covered by a flow channel. Meanwhile the various channels are being supplied with the necessary gaseous materials in Step 1. Simultaneous with Sequence 15 in FIG. 1, other adjacent channel areas are being processed simultaneously, which results in multiple channel flows in parallel, as indicated in overall Step 11.

The primary purpose of the second molecular precursor is to condition the substrate surface back toward reactivity with the first molecular precursor. The second molecular precursor also provides material as a molecular gas to combine with one or more metal compounds at the surface, forming titanium dioxide with the freshly deposited titanium-containing precursor.

The continuous ALD purge does not need to use a vacuum purge to remove a molecular precursor after applying it to the substrate.

Assuming that two reactant gases, AX and BY, are used, when the gas AX flow is supplied and flowed over a given substrate area, atoms of the gas AX are chemically adsorbed on a substrate, resulting in a layer of A and a surface of ligand X (associative chemisorptions) (Step 2). Then, the remaining gas AX is purged with an inert gas (Step 4). Then, gas BY is flowed over the surface and a chemical reaction between AX (surface) and BY (gas) occurs, resulting in a molecular layer of AB on the substrate (dissociative chemisorptions) (Step 6). The remaining gas BY and by-products of the reaction are purged (Step 8). The thickness of the thin film can be increased by repeating the process cycle (Steps 2-9).

Because the film can be deposited one monolayer at a time it tends to be conformal and have uniform thickness.

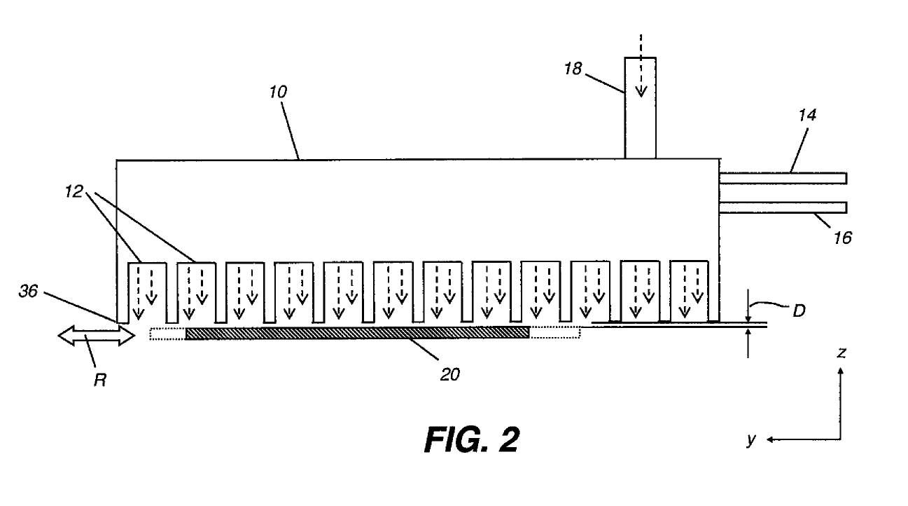

Referring now to FIG. 2, there is shown a cross-sectional side view of one embodiment of a distribution manifold 10 that can be used in the present process for ALD onto a substrate 20. Distribution manifold 10 has a gas inlet port 14 for accepting a first gaseous material, a gas inlet port 16 for accepting a second gaseous material, and a gas inlet port 18 for accepting a third gaseous material. These gases are emitted at an output face 36 via output channels 12, having a structural arrangement as described below. The arrows in FIG. 2 refer to the diffusive transport of the gaseous material, and not to the flow received from an output channel. The flow is substantially directed out of the page of the Figure.

Gas inlet ports 14 and 16 are adapted to accept first and second gases that react sequentially on the substrate surface to effect ALD deposition, and gas inlet port 18 receives a purge gas that is inert with respect to the first and second gases. Distribution manifold 10 is spaced a distance D from substrate 20, provided on a substrate support. Reciprocating motion can be provided between substrate 20 and distribution manifold 10, either by movement of substrate 20, by movement of distribution manifold 10, or by movement of both substrate 20 and distribution manifold 10. In the particular embodiment shown in FIG. 2, substrate 20 is moved across output face 36 in reciprocating fashion, as indicated by the arrow R and by phantom outlines to the right and left of substrate 20 in

FIG. 2. It should be noted that reciprocating motion is not always required for thin-film deposition using distribution manifold 10. Other types of relative motion between substrate 20 and distribution manifold 10 could also be provided, such as movement of either substrate 20 or distribution manifold 10 in one or more directions.

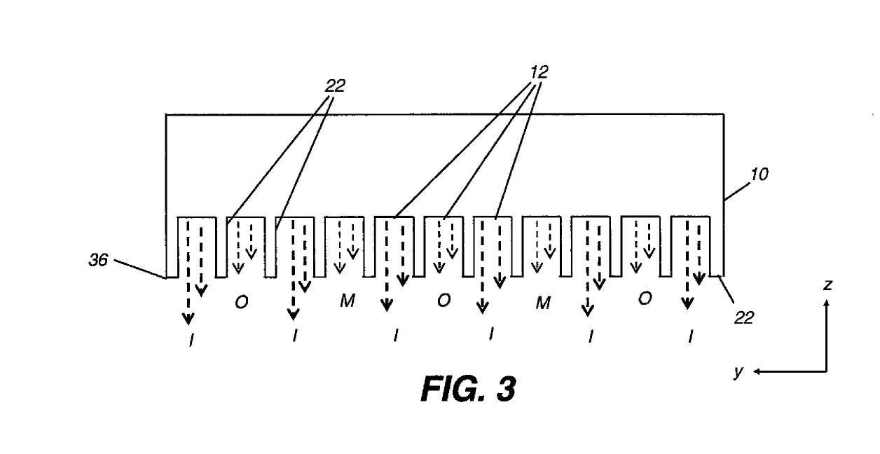

The cross-sectional view of FIG. 3 shows gas flows emitted over a portion of front face 36 of distribution manifold 10. In this particular arrangement, each output channel 12 is in gaseous flow communication with one of gas inlet ports 14, 16 or 18 seen in FIG. 2. Each output channel 12 delivers typically a first reactant gaseous material O, or a second reactant gaseous material M, or a third inert gaseous material I.

FIG. 3 shows a relatively basic or simple arrangement of gases. It is possible that a plurality of non-metal deposition precursors (like material O) or a plurality of titanium-containing precursor materials (like material M) may be delivered sequentially at various ports in a thin-film single deposition. The critical requirement is that an inert stream labelled I should separate any reactant channels in which the gases are likely to react with each other. First and second reactant gaseous materials O and M react with each other to effect ALD deposition, but neither reactant gaseous material O nor M reacts with inert gaseous material I.

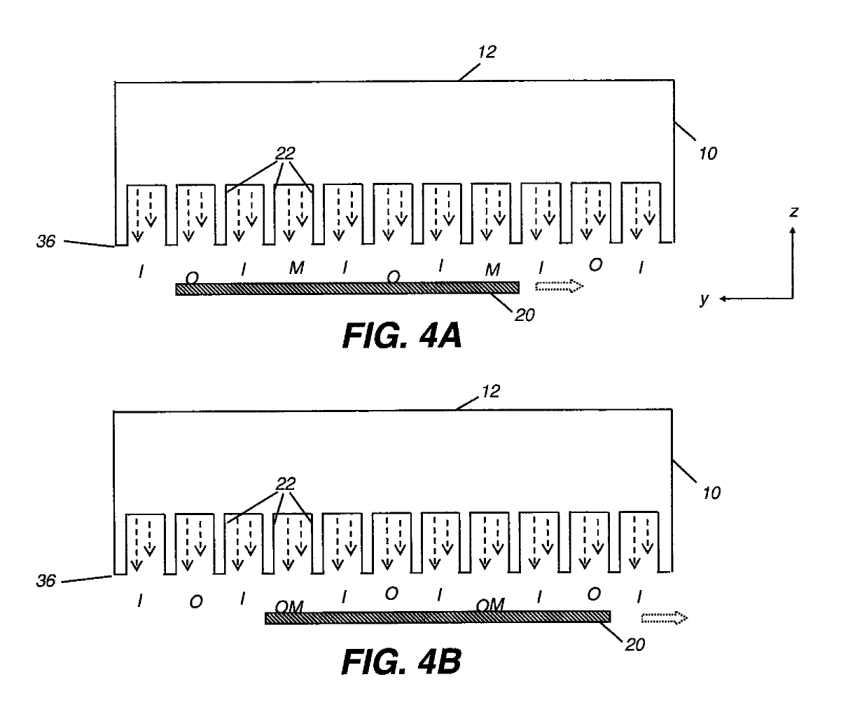

The cross-sectional views of FIGS. 4A and 4B show, in simplified schematic form, the ALD coating operation performed as substrate 20 passes along output face 36 of distribution manifold 10 when delivering reactant gaseous materials O and M. In FIG. 4A, the surface of substrate 20 first receives an oxidizing material from output channels 12 designated as delivering first reactant gaseous material O. The surface of the substrate now contains a partially reacted form of material O, which is susceptible to reaction with material M. Then, as substrate 20 passes into the path of the metal compound of second reactant gaseous material M, the reaction with M takes place, forming titanium dioxide.

As FIGS. 4A and 4B show, inert gaseous material I is provided in every alternate output channel 12, between the flows of first and second reactant gaseous materials O and M. Sequential output channels 12 are adjacent, that is, share a common boundary, formed by partitions 22 in the embodiments shown. Here, output channels 12 are defined and separated from each other by partitions 22 that extend perpendicular to the surface of substrate 20.

Notably, there are no vacuum channels interspersed between the output channels 12, i.e. there are no vacuum channels on either side of a channel delivering gaseous materials to draw the gaseous materials around the partitions. This advantageous, compact arrangement is possible because of the innovative gas flow that is used. Unlike gas delivery arrays of earlier processes that apply substantially vertical (that is, perpendicular) gas flows against the substrate and draw off spent gases in the opposite vertical direction, distribution manifold 10 directs a gas flow (preferably substantially laminar in one embodiment) along the surface for each reactant and inert gas and handles spent gases and reaction by-products in a different manner. The gas flow used in the present invention is directed along and generally parallel to the plane of the substrate surface so that the flow of gases is substantially transverse to the plane of a substrate rather than perpendicular to the substrate being treated.

The patents and publications referred to herein are incorporated by reference in their entirety.

The invention will now be described with reference to the following examples which are, however, in no way to be construed as limiting thereof.

### Examples

In all the examples ALD/CVD coating with titanium oxide was carried out using apparatus similar to that described above, with titanium tetrachloride in one bubbler and water in the other. The flow rate of the carrier gas through the bubblers was 50 ml/min. The flow rate of diluting carrier gas was 200 ml/min for the water reactant and 150 ml/min for the titanium tetrachloride. The flow rate of the inert separator gas was 2 l/min. Nitrogen was used for the carrier gas in all instances.

A series of calibration coatings was made for the titanium dioxide by coating a series of coatings made with different numbers of oscillations of the substrate under the coating manifold. The thickness of these coatings was determined using an α-SE ellipsometer (Woollam) so that a calibration curve of thickness v. oscillation number could be obtained. A calibration curve was made for all the substrate temperatures tested.

### Example 1 (Invention)

A coating of titanium dioxide was deposited using a spatial ALD onto grained and anodized aluminum. The layer thickness was approximately 25 nm and the deposition temperature was 200° C. Half of the sample was exposed to ultra-violet radiation for 20 min. using a Theimer™, ‘Spektraproof Daylight’™ contact frame fitted with a 2.5 kW ‘metal halogen’ bulb at a distance of 1 m through a quartz window (estimated energy of the exposure in the region where titanium dioxide absorbs is 300 mJ/cm²).

The Status A and Visual densities of the exposed and unexposed images were each measured at three points using an X-rite™ densitometer and the static contact angle with ‘Millipore’ water was also measured for both exposed and unexposed regions.

| | Visual | Red | Green | Blue | Contact |
|---|---|---|---|---|---|
| Sample | density | density | density | density | Angle (deg) |
| Unexposed | 0.279 | 0.291 | 0.282 | 0.275 | 64 |
| Exposed | 0.295 | 0.302 | 0.296 | 0.288 | ≦5 |
| Difference | +0.016 | +0.011 | +0.014 | +0.013 | |
| Exp − Unexp | | | | | |

TABLE 1 shows the averaged results which show that in each instance the exposed image area had a higher density than the unexposed area. This density difference was clearly visible to the unaided eye. There was a contact angle differential between the unexposed and exposed regions, thus indicating that the plate is suitable for lithographic printing.

### Example 2 (Invention)

A layer of 25 nm of aluminum was vapour deposited onto aluminum by the same method as described above for titanium and with the same settings on the spatial ALD device, except that titanium tetrachloride was replaced with trimethylaluminium. Onto this was coated a 25 nm layer of titanium dioxide as described in Example 1. Half of the sample was exposed to ultra-violet radiation for 20 min. using a Theimer™, ‘Spektraproof Daylight’™ contact frame fitted with a 2.5 kW ‘metal halogen’ bulb at a distance of 1 m through a quartz window (estimated energy of the exposure in the region where titanium dioxide absorbs is 300 mJ/cm²).

The Status A blue density of seven points on the exposed and unexposed images areas were measured using an X-rite™ densitometer. The average density of the exposed plate was 0.72 and of the unexposed plate was 0.675, showing a clear optical density differential, so that it could be readily determined whether or not a plate had been exposed

### Example 3 (Comparative Example)

A coating of titanium dioxide was deposited onto a 0.1 mm thick transparent PEN plastic sheet using a spatial ALD device. The layer thickness was approx. 25 nm and the deposition temperature was 100° C. Half of each sample was exposed to ultra-violet radiation for 20 min. using a Theimer™, ‘Spektraproof Daylight’™ contact frame fitted with a 2.5 kW ‘metal halogen’ bulb at a distance of 1 m through a quartz window. A piece of white paper was placed behind the sheet. No image could be seen.

### Example 4 (Comparative Example)

A coating of titanium dioxide was deposited using a spatial ALD device onto a sheet of Technova Novadom™ 5000, a white, clay-coated hydrophilic layer suitable for lithographic printing. The layer thickness was approx. 25 nm and the deposition temperature was 100° C. Half of each sample was exposed to ultra-violet radiation for 20 min. using a Theimer™, ‘Spektraproof Daylight’™ contact frame fitted with a 2.5 kW ‘metal halogen’ bulb at a distance of 1 m through a quartz window. No image could be seen.

The invention has been described in detail with particular reference to certain preferred embodiments thereof, but it will be understood that variations and modifications can be effected within the spirit and scope of the invention.

1. A method of differentiating an unexposed planographic printing plate from an exposed planographic printing plate by means of making a planographic printing plate comprising a substrate having thereon one or more layers of aluminum oxide, and one or more layers of radiation-sensitive titanium dioxide coated thereon and excluding an organic hydrophobic material or a binder within or above a radiation-sensitive layer, the method comprising depositing at least the one or more layers of titanium dioxide by vapour deposition and exposing the one or more layers to radiation without that exposure causing an ablative effect.

2. The method according to claim 1 wherein the titanium dioxide is deposited as one or more layers by atomic layer deposition.

3. The method according to claim 2 whereby the atomic layer deposition process takes place at atmospheric pressure.

4. The method according to claim 1 whereby the process takes place at a temperature from 20° C. to 300° C.

5. The method according to claim 1 wherein the aluminum oxide is deposited as one or more layers by vapour deposition.

6. The method according to claim 5 wherein the aluminum oxide is deposited as one or more layers by atomic layer deposition.

7. The method according to claim 1 wherein the substrate is aluminum that has been grained and anodized.

8. The method according to claim 1 where the titanium dioxide is prepared from a titanium tetrachloride precursor.

9. The method according to claim 1 wherein the titanium dioxide is less than 100 nm thick.

10. The method according to claim 9 wherein the titanium dioxide layer is less than 25 nm thick.

11. The method according to claim 1 wherein the substrate is polyethylene terephthalate, polyethylene naphthalate, polyimide, paper, flexible glass, or a composite thereof.
